(19) United States
(12) Patent Application Publication
(10) Pub. No.: US 2016/0081195 A1
(43) Pub. Date: Mar. 17, 2016

(54) DETACH CORE SUBSTRATE AND METHOD FOR MANUFACTURING THEREOF

(71) Applicant: Samsung Electro-Mechanics Co., Ltd., Suwon-si (KR)

(72) Inventors: Yong Yoon CHO, Suwon-si (KR); Ki Hwan KIM, Suwon-si (KR); Gun Woo KIM, Seoul (KR); Sung Won JEONG, Changwon-si (KR); Gi Ho HAN, Hwaseong-si (KR); Da Hee KIM, Seoul (KR)

(73) Assignee: Samsung Electro-Mechanics Co., Ltd., Suwon-si (KR)

(21) Appl. No.: 14/851,929

(22) Filed: Sep. 11, 2015

(30) Foreign Application Priority Data
Sep. 17, 2014 (KR) 10-2014-0123547

(51) Int. Cl. H05K 3/00; H05K 1/02; H05K 3/46

(52) U.S. Cl. CPC H05K 3/007; H05K 3/4682; H05K 1/0298

(57) ABSTRACT

The present invention relates to a detach core substrate and a method of manufacturing a detach core substrate. In accordance with one embodiment of the present invention, there is proposed a detach core substrate that a conductive layer including a metal layer with an etching property different from copper is formed on a top surface and a bottom surface of an insulating layer formed thereon a surface roughness. At this time, the contact interface between the top surface and the bottom surface of the insulating layer is the detachment interface to be separated during the manufacture of the circuit board. In addition, a method of manufacturing the detach core substrate is proposed.

### CROSS-REFERENCE TO RELATED APPLICATIONS

Claim and incorporate by reference domestic priority application and foreign priority application as follows:

### CROSS REFERENCE TO RELATED APPLICATION

This application claims the benefit under 35 U.S.C. Section 119 of Korean Patent Application Serial No. 10-2014-0123547, entitled filed Sep. 17, 2014, which is hereby incorporated by reference in its entirety into this application.

### BACKGROUND OF THE INVENTION

1. Field of the Invention

The present invention relates to a detach core substrate and a method for manufacturing thereof; and, more particularly to a detach core substrate formed thereof a conductive layer including a metal layer with an etching property different from copper and a method for manufacturing thereof.

2. Description of the Related Art

In recent, as the slimness of substrates, the reduction of resistance, the manufacturing of odd number layers or the like can be possible by using a detach core, the demands of the detach core substrate have been increased.

In case of a conventional detach core, the cored copper layer and the carrier stacked on the core copper layer are manufactured by being simply pressed or applying a very low adhesive strength. At this time, according to the solution penetration due to the low adhesive strength, since the manufacturing equipment is damaged due to the penetrated chemical or the quality risk such as to generate the failure in the whole panel, the improvement of the solution penetration has been continuously tried.

And also, in case of a conventional detach core substrate, the plating thickness decrement and the loss of pattern due to the over etching may be generated. In case when the copper foil applied as a seed layer is etched after the carrier separation, due to an insulating layer, e.g., a tooth of PPG, it is required to be over etched to a certain degree in comparison with the thickness of copper foil. In this case, the thickness of the formed pattern becomes thin, the pattern is lost according to the deviation or the dimple is generated.

### SUMMARY OF THE INVENTION

In order to solve the above-described problems, the present invention proposes a detach core substrate that a conductive layer including a metal layer with an etching property different from copper is formed on a top surface and a bottom surface of an insulating layer formed thereon a surface roughness and a method for manufacturing the same.

In order to solve the above-described problems, the present invention proposes a detach core substrate that a conductive layer including a metal layer with an etching property different from copper is formed on a top surface and a bottom surface of an insulating layer formed thereon a surface roughness. For example, the metal layer has an etch resistance during the copper etching. The interface between the top surface and the bottom surface of the insulating layer and the conductive layer is the detachment interface to be detached during the manufacture of the circuit board. At this time, the contact force of the contact interface may be ranged from 0.05 Igf/cm² to 0.2 kgf/cm².

In one example, the metal layers are formed on the top surface and the bottom surface of the insulating layer, respectively; or, formed on the first copper layers formed on the top surface and the bottom surface of the insulating layer, respectively. And also, the second copper layers are further formed on each of the metal layers.

In addition, in order to solve the above-described problems, the present invention proposes a method of manufacturing a detach core substrate including a step of forming a conductive layer having a metal layer with an etching property different from copper on a top surface and a bottom surface of an insulating layer formed thereon a surface roughness. For example, the metal layer has an etch resistance during the copper etching. The contact interface between the top surface and the bottom surface of the insulating layer and the conductive layer is formed to be separated during the manufacture of the circuit board.

In one example, the metal layer is formed on the top surface and the bottom surface of the insulating layer by the electroless plating or the sputtering; or, the metal layer can be formed on the first copper layer formed on the top surface and the bottom surface of the insulating layer by the chemical plating or the sputtering can be formed by the electroless plating or the sputtering. In addition, the second copper layer can be further formed on each of the metal layer by the electroplating or the sputtering.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1 is an exploded diagram showing a detach core substrate in accordance with one embodiment of the present invention;

FIGS. 2A to 2C are cross-sectional views schematically showing the detach core substrate in accordance with another embodiment of the present invention, respectively;

FIG. 3 is a flowchart schematically showing a method for manufacturing the detach core substrate in accordance with still another embodiment of the present invention; and

FIGS. 4A to 4C are flowcharts schematically showing the method for manufacturing the detach core substrate in accordance with still another embodiment of the present invention, respectively.

### DETAILED DESCRIPTION OF THE PREFERABLE EMBODIMENTS

Embodiments of the present invention to achieve the above-described objects will be described with reference to the accompanying drawings. In this description, the same elements are represented by the same reference numerals, and additional description which is repeated or limits interpretation of the meaning of the invention may be omitted.

In this specification, when an element is referred to as being “connected” or “coupled” to another element, it can be “directly” connected or coupled to the other element or connected or coupled to the other element with another element interposed therebetween, unless it is referred to as being “directly connected” or “directly coupled” to the other element.

Reference in the specification to “connect” or “connecting”, as well as other variations thereof, means that an element is directly connected to the other element or indirectly connected to the other element through another element. Throughout this specification, the singular form includes the plural form unless the context clearly indicates otherwise. When terms “comprises” and/or “comprising” used herein do not preclude existence and addition of another component, step, operation and/or device, in addition to the above-mentioned component, step, operation and/or device.

The drawings referenced in this specification are provided as examples to describe the embodiments of the present invention, and the shape, size, and thickness may be exaggerated in the drawings for effective description of technical features.

And also, in the present specification, as a first copper layer and a second copper layer are to discriminate a first and a second, it means that two single layers are formed with only one copper layer independently as well as formed with individual layer together may be used.

The detach core substrate in accordance with another aspect of the present invention will be described in detail with reference to the accompanying drawings. At this time, the same components are represented by the same reference numerals hereinafter.

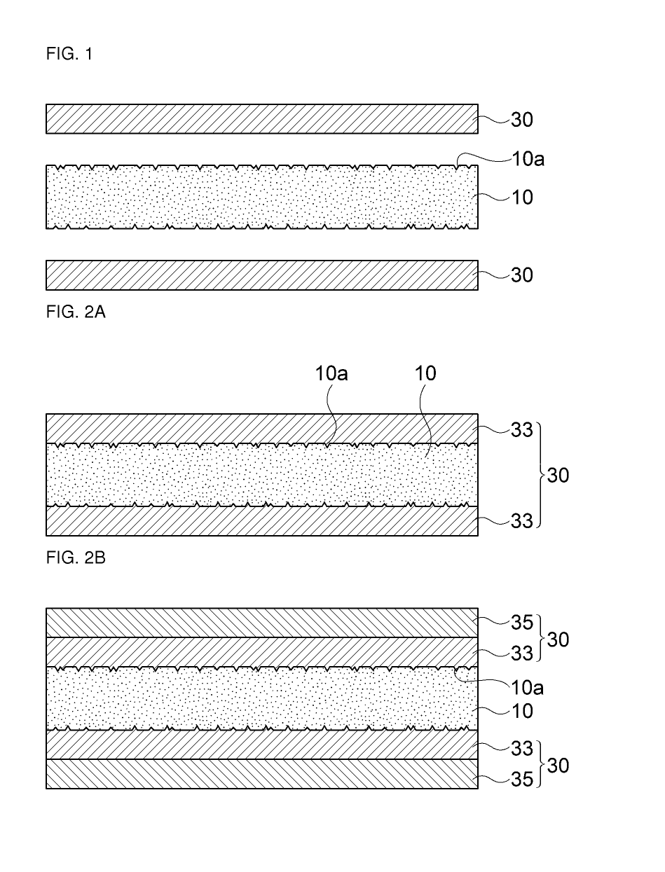

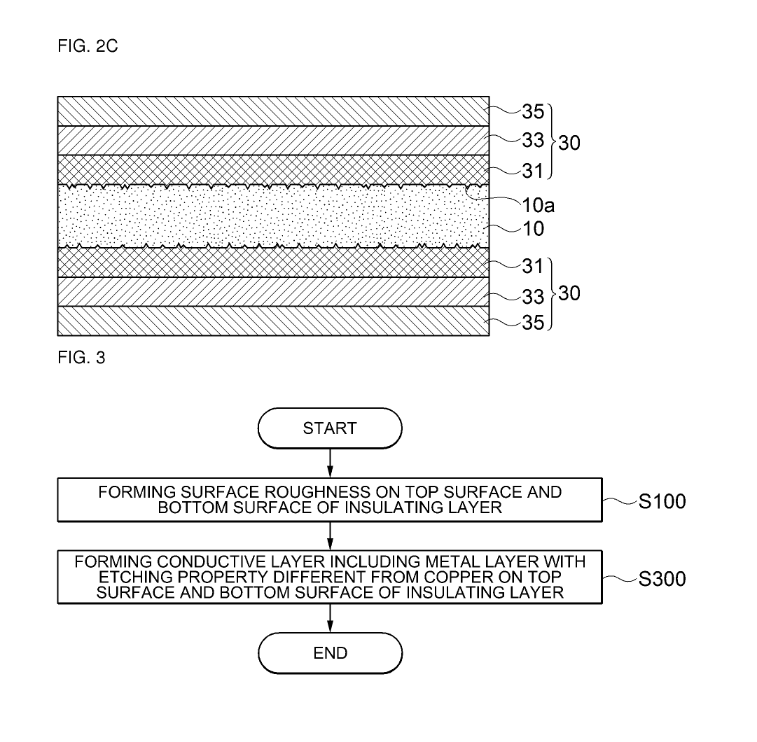

FIG. 1 is an exploded diagram showing a detach core substrate in accordance with one embodiment of the present invention, and FIGS. 2A to 2C are cross-sectional views schematically showing the detach core substrate in accordance with another embodiment of the present invention, respectively.

Referring to FIG. 1, the detach core substrate in accordance with one example includes an insulating layer 10 and a conductive layer 30 formed on both of a top surface and a bottom surface of the insulating layer 10. At this time, the interfaces between the top surface and the bottom surface of the insulating layer 10 and the conductive layer 30 are detachment interfaces to be separated during the manufacturing of a circuit board.

The surface roughness 10a is formed on the top surface and the bottom surface of the insulating layer 10a. For example, in one example, the average surface roughness of the both surfaces of the insulating layer 10 may be 0.1˜10 μm. At this time, the average surface roughness may be an arithmetic mean roughness Ra or a ten point average roughness Rz. For example, the insulating layer 10 may be formed of a resin material and, in one example, may be formed of the PPG (Prepreg). The material of the insulating material 10 is not limited to the resin or the PPG, but it may be used by selecting one among the other material used for the substrate or the detach core substrate.

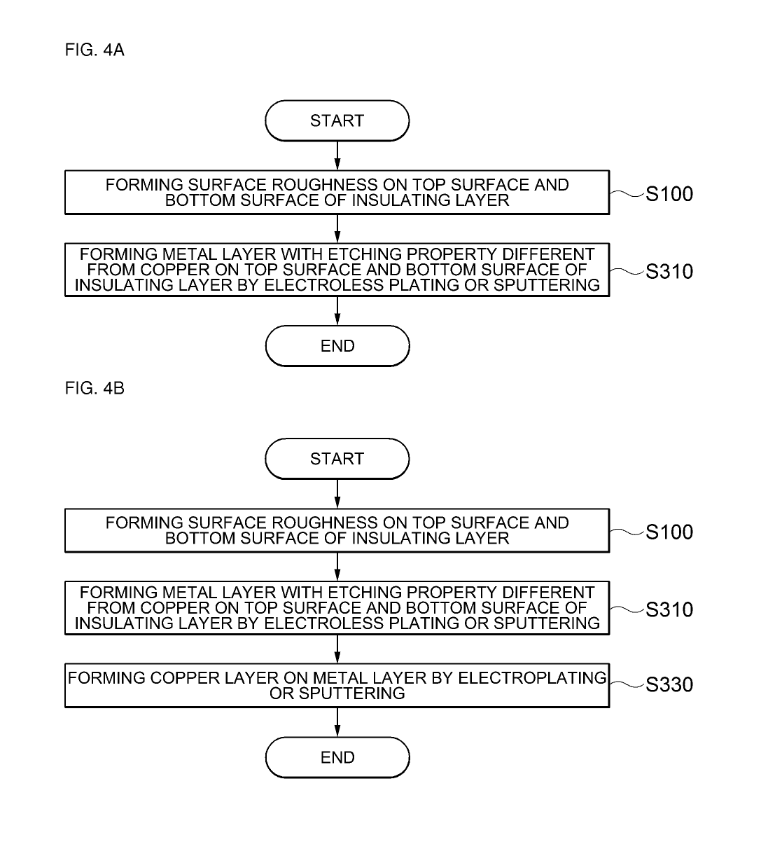

The conductive layer 30 formed on the top surface and the bottom surface of the insulating layer 10 includes the metal layer 33 with an etching property different from the copper. Referring to FIG. 2A, the conductive layer 30 is formed of only the metal layer 33, referring to FIG. 2B, is formed by including the metal layer 33 and the second copper layer 35, referring to FIG. 2C, is formed by including the first copper layer 31, the metal layer 33 and the second copper layer 35, not shown directly but referring to FIG. 3C, or may be formed by including the first copper layer 31 and the metal layer 33. For example, at this time, the thickness of the conductive layer 30 may be ranged from 0.05 μm to 210 μm.

In one example, the metal layer 33 has the etch resistance during the copper etching. That is, the metal layer 33 may be a selective etching metal which is not etched during the copper etching in manufacturing a multi-layer substrate or the like using the detach core substrate. Accordingly, when the substrate is manufactured by using the detach core substrate, since an etch barrier layer is formed as the metal layer 33 with the etching property different from the copper, after the detachment of the detach core substrate, the present invention prevents the thickness of patterns from being reduced or lost and the dimple can be prevented when the copper layer of the peripheral region of the metal layer 33 is etched. For example, after etching the peripheral region of copper layer, the metal layer is additionally etched or the etching is not performed when the etching is not required as occasion demands. In the embodiment of the present invention, the selective etching can be applied as the metal layer 33 with the etching property different from the copper, and the protection of the quality of products of the detach interface, e.g., the thickness degrade and the loss of patterns can be protected.

For example, the metal having the etching property different from the copper may be Ni or Ti. That is, in one example, the metal layer 33 can include Ni or Ti material.

Referring to FIG. 2A or/and FIG. 2B, in one example, the metal layer 33 may be formed on the top surface and the bottom surface of the insulating layer 10, respectively.

At this time, referring to FIG. 2B, the conductive layer 30 can include the metal layer 33 and the copper layer. For example, the second copper layer 35 may be further formed on the outside surface of the metal layer 33, respectively. At this time, ‘the second’ of the second copper layer 35 is added simply to discriminate from ‘the first copper layer’ as described hereinafter. That is, in the embodiment of the present invention, the second copper layer is formed only one copper layer independently, but it need not to include the first copper layer additionally.

And also, referring to FIG. 2C, in one example, the first copper layer 31 is formed between the metal layer 33 the top surface and the bottom surface of the insulating layer 10. In one example, as not directly shown, the conductive layer 30 may be formed by including the first copper layer 31 and the metal layer 33, in another example as shown in FIG. 2C, the conductive layer 30 can include the first copper layer 31, the metal layer 33 and the second copper layer 35. At this time, the first copper layer is formed on each of the top surface and the bottom surface of the insulating layer 10, respectively, and the metal layer 33 is formed on each of the first copper layers 31 on the top surface and the bottom surface of the insulating layer 10. And also, referring to FIG. 2C, the second copper layer 35 is formed on each of the outer surfaces of the metal layer.

And also, the adhesive strength of the contact interface between the top surface and the bottom surface of the insulating layer 10 having the surface roughness 10a and the conductive layer 30 may be 0.05˜0.2 kgf/cm². For example, the conductive layer 30 being in contact with the top surface and the bottom surface of the insulating layer 10 may be formed by using the electroless plating or the sputtering. For example, in case when applying the sputtering having a low adhesive strength, the adhesive strength becomes the value below 0.15 kgf/cm² when Ti is sputtered on the PPG insulating layer 10, and the adhesive strength below 0.2 kgf/cm² can be obtained by the electroless plating.

In case of a conventional detach core substrate, since the contact force of the detachment interface between the chemical copper and the PPG is very low at the degree of approximately 0.01˜0.05 kgf/cm², the reliability of products becomes degraded; and, in case when a small gap is generated, the solution penetration can be easily generated in the process of wet line. However, in the embodiment of the present invention, in case when the adhesive strength can controlled according to the process conditions using the metal layer 33, the possibility of solution penetration can be degraded even when the gap is separated. In case of FIG. 2C, since the copper layer and the insulating layer 10 form the contact interface, in this case, the contact force may be changed according to the voltage and the pre-treatment conditions of Cu sputtering.

And also, when the detach core substrate in accordance with one embodiment of the present invention is used, since the conductive layer 30 is separated at the detachment interface, the waste reduction, the recycle cost reduction and the like are allowable since the discarded part is only the insulating layer of the detach core substrate.

Thereafter, the method for manufacturing the detach core substrate in accordance with another aspect of the present invention will be described in detail with reference to the drawings. At this time, this aspect can be described with reference to the detach core substrate in accordance with the above-described aspect of the present invention and FIG. 1 to FIG. 2C; and, accordingly, the overlapped explanation will be omitted.

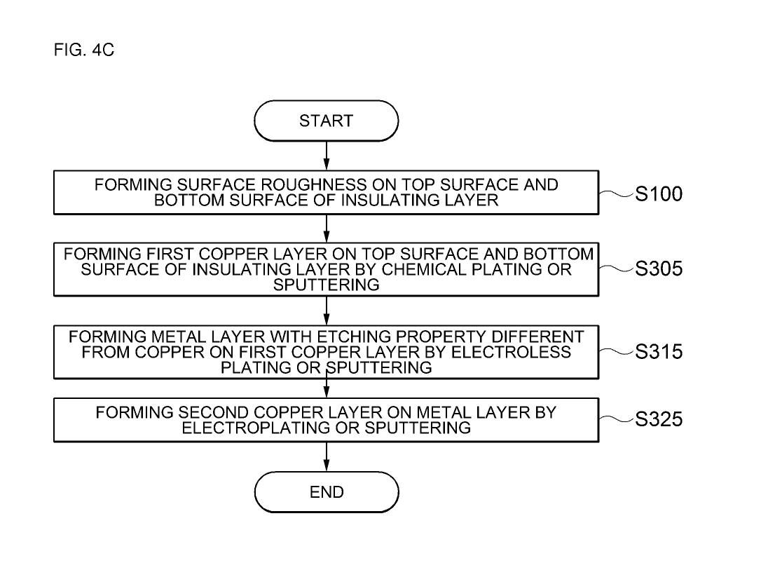

FIG. 3 is a flowchart schematically showing the method for manufacturing the detach core substrate in accordance with still another embodiment of the present invention, and FIGS. 4A to 4C are flowcharts schematically showing the method for manufacturing the detach core substrate in accordance with still another embodiment of the present invention, respectively.

Referring to FIG. 3, in one example, the method for manufacturing the detach core substrate includes a step of forming a surface roughness (S100) and a step of forming a conductive layer (S300).

In the step of forming the surface roughness (S100), the surface roughness 10a is formed on the top surface and the bottom surface of the insulating layer 10. For example, the roughness is formed on the surfaces of the insulating layer 10 such as the harden insulation resin or the PPG or the like. According to forming the roughness, the contact force of the adhesive interface or the detachment interface between the conductive layers 30 attached to the top surface and the bottom surface of the insulating layer 10 in the following processes can be controlled. The detachment interface of the present specification means the interface to be separated in the process to remove the detach core substrate when the multi-layer substrate is manufactured by using the detach core substrate of the present invention. The method of forming the surface roughness may be a de-smear process or a polishing process or the like. For example, the average surface roughness of 0.1˜10 μm can be formed on the top surface of the bottom surface of the insulating layer 10 through the polishing or the de-smear process or the like. For example, although the delamination may be easily performed after the chemical copper growth layer even in the case that the roughness is not almost formed by hardening only the insulating layer, but if the surface roughness is formed, the stable chemical copper can be grown. The contact force of the conductive layer 30 can be changed according to such roughness, the contact force of the conductive layer 30 can be controlled.

For example, at this time, the insulating layer 10 may be formed of the resin or the PPG (Prepreg) material.

Thereafter, in the step of forming the conductive layer (S300), the conductive layers 30 including the metal layer 33 with the etching property different form the copper are formed on the top surface and the bottom surface of the insulting layer 10, respectively. At this time, the contact interface between the top surface and the bottom surface of the insulating layer 10 and the conductive layer 30 is formed to be separated when a circuit board is manufactured. For example, the conductive layer 30 may be formed in such a way that the contact force of the contact interface is ranged from 0.05 kgf/cm² to 0.2 kgf/cm².

And also, at this time, in one example, the metal layer 33 with the etching property different from the copper has the etch resistance during the copper etching in the manufacturing process of the substrate using the following detach core substrate. For example, the metal layer 33 may be formed by including Ni or Ti material.

In another example, the thickness of the conductive layer 30 may be formed in the range of 0.05 μm to 210 μm.

Next, referring to FIG. 4A to FIG. 4C, the step for forming the conductive layer will be described in detail.

Reviewing with reference to FIG. 4A to 4C, in the step of forming the conductive layer, the metal layer 33 can be formed on the top surface and the bottom surface of the insulating layer 10 by the electroless plating or the sputtering (S310).

At this time, referring to FIG. 4A, in one example, in the step of forming the conductive layer, after the step of forming the metal layer, a step of forming a second copper layer (S330) can be further included. That is, in the step of forming the conductive layer, the step of forming the second copper layer 35 can be further performed on each of the outer surfaces of the metal layer 33 by using the electroplating or the sputtering. At this time, as ‘the second copper layer’ is to discriminate from ‘the first copper layer’, two single layers are formed with only one copper layer independently as well as formed with individual layer together may be used.

Although not shown directly, referring to FIG. 4C, in one example, the step of forming the conductive layer can be formed by including a step of forming the first copper layer (S305) and a step of forming the metal layer (S315). That is, in FIG. 4C, the conductive layer 30 can be formed in the method except the step of forming the second copper layer. At this time, the first copper layer 31 is formed on the top surface and the bottom surface of the insulating layer 10 by the chemical plating or the sputtering (S305), and the metal layer 33 can be formed on each of the outer surfaces of the first copper layer by the electroless plating or the sputtering (S315).

And also, referring to FIG. 4C, in one example, the step of forming the conductive layer can be formed by including a step of forming the first copper layer (S305), a step of forming the metal layer (S315) and a step of forming the second copper layer (S325). At this time, the first copper layer 31 is formed on the top surface and the bottom surface of the insulating layer 10 by the chemical plating or the sputtering (S305), the metal layer 33 can be formed on each of the outer surfaces of the first copper layer by the electroless plating or the sputtering (S315) and the second copper layer 35 can be formed on each of the outer surfaces of the metal layer 33 by using any one among the eletroplating and the sputtering (S325).

In accordance with one embodiment of the present invention, the problem according to the over-etching can be solved by forming the conductive layer including the metal layer with the etching property different from the copper on each of the top surface and the bottom surface of the insulating layer formed thereon the surface roughness.

And also, in accordance with another example of the present invention, the problem of solution penetration can be improved by improving the contact force of the detachment interface of the detach core substrate.

Although various effects in accordance with various embodiments of the present invention are not directly mentioned, they can be understood and derived from the combinations of elements of each embodiment by those skilled in the art.

As described above, the foregoing description illustrates the present invention. Additionally, the foregoing description shows and explains only the preferred embodiments of the present invention, but it is to be understood that the present invention is capable of use in various other combinations, modifications, and environments and is capable of changes and modifications within the scope of the inventive concept as expressed herein, commensurate with the above teachings and/or the skill or knowledge of the related art. The embodiments described hereinabove are further intended to explain best modes known of practicing the invention and to enable others skilled in the art to utilize the invention in such, or other, embodiments and with the various modifications required by the particular applications or uses of the invention. Accordingly, the description is not intended to limit the invention to the form disclosed herein. Also, it is intended that the appended claims be construed to include alternative embodiments.

What is claimed is:

1. A detach core substrate comprising:
an insulating layer provided with a top surface and a bottom surface where surface roughness is formed; and
conductive layers including a metal layer with an etching property different from copper and formed on the top surface and the bottom surface of the insulating layer, respectively,
wherein interfaces between the top surface and the bottom surface of the insulating layer and the conductive layers are detachment interfaces to be separated during manufacturing a circuit board.

2. The detach core substrate according to claim 1, wherein the metal layer is formed on the top surface and the bottom surface of the insulating layer, respectively.

3. The detach core substrate according to claim 1, wherein the conductive layer further includes:
a first copper layer formed between the metal layer and the top surface and the bottom surface of the insulating layer, respectively.

4. The detach core substrate according to claim 2, wherein the conductive layer further includes:
a second copper layer formed on each outer side surface of the metal layer.

5. The detach core substrate according to claim 1, wherein the metal layer has an etch resistance during copper etching.

6. The detach core substrate according to claim 5, wherein the metal layer includes Ni or Ti material.

7. The detach core substrate according to claim 1, wherein an adhesive force of interfaces between the top surface and the bottom surface of the insulating layer and the conductive layers is ranging from 0.05 kgf/cm² to 0.2 kgf/cm².

8. The detach core substrate according to claim 1, wherein an average surface roughness of both the top surface and the bottom surface of the insulating layer is ranging from 0.1 μm to 10 μm.

9. The detach core substrate according to claim 1, wherein a thickness of the conductive layer is ranging from 0.05 μm to 210 mμ.

10. A method for manufacturing a detach core substrate comprising:
forming surface roughness on a top surface and a bottom surface of an insulating layer; and
forming a conductive layer including a metal layer with an etching property different from copper on the top surface and the bottom surface of the insulating layer,
wherein interfaces between the top surface and the bottom surface of the insulating layer and the conductive layer are formed to be separated during manufacturing a circuit board.

11. The method for manufacturing the detach core substrate according to claim 10, wherein, in forming the conductive layer on the top surface and the bottom surface of the insulating layer, the metal layer is formed on the top surface and the bottom surface of the insulating layer by an electroless plating or a sputtering.

12. The method for manufacturing the detach core substrate according to claim 10, wherein, in forming the conductive layer on the top surface and the bottom surface of the insulating layer, respectively, a first copper layer is formed on the top surface and the bottom surface of the insulating layer by a chemical plating or a sputtering, respectively, and the metal layer is formed on an outside surface of the first copper layer by an electroless plating or a sputtering, respectively.

13. The method for manufacturing the detach core substrate according to claim 11, wherein, in forming the conductive layer on the top surface and the bottom surface of the insulating layer, respectively, a process of forming a second copper layer on an outside surface of the metal layer is performed by an electroplating or a sputtering.

14. The method for manufacturing the detach core substrate according to claim 10, wherein the metal layer has an etch resistance during a copper etching.

15. The method for manufacturing the detach core substrate according to claim 14, wherein the metal layer is formed by including Ni or Ti material.
